(19) United States
(12) Patent Application Publication
(10) Pub. No.: US 2002/0140030 A1
(43) Pub. Date: Oct. 3, 2002

(54) SOI devices with integrated gettering structure

(76) Inventors: Jack A. Mandelman, Stormville, NY (US); Jeffrey P. Gambino, Westford, VT (US); Jerome B. Lasky, Essex Junction, VT (US); Carl J. Radens, LaGrangeville, NY (US); Steven H. Voldman, South Burlington, VT (US)

Correspondence Address: INTERNATIONAL BUSINESS MACHINES CORPORATION, DEPT. 18G, BLDG. 300-482, 2070 ROUTE 52, HOPEWELL JUNCTION, NY, 12533, US

(21) Appl. No.: 09/822,431

(22) Filed: Mar. 30, 2001

(51) Int. Cl. H01L 27/01

(52) U.S. Cl. 257/347; 257/349; 257/350; 257/913

(57) ABSTRACT

An SOI wafer has a set of gettering sites formed in the device layer, optionally extending through the buried insulator; the gettering sites being formed within the source/drain regions of transistors.

### FIELD OF THE INVENTION

The field of the invention is SOI integrated circuit processing.

### BACKGROUND OF THE INVENTION

The need for gettering to remove metallic contaminants from sensitive parts of the devices such as gate oxide, channel and junctions of SOI MOS circuits is well known. Prior art approaches have included formation of a buried poly layer (Reduction of PN Junction Leakage Current by Using Poly-Si Interlayered SOI Wafers, Horiuchi and Ohoyu, IEEE Transactions on Electron Devices, Vol 42, No. 5, May 1995) and forming body contacts. A drawback of the former approach is significantly increased process complexity and cost and of the latter approach is that the body contact must be of the same dopant polarity as the body and thus increases the active area.

### SUMMARY OF THE INVENTION

The invention relates to an SOI structure that includes gettering members formed within the set of active areas that contain transistors or other devices.

A feature of the invention is the formation of gettering members integrated within the source/drain S/D areas of transistors.

An optional feature of the invention is the penetration of a gettering member into the buried insulator layer.

### BRIEF DESCRIPTION OF THE DRAWINGS

FIG. 1 shows a cross section of prior art SOI devices without gettering members.

FIG. 2a shows a cross section of an embodiment of the invention.

FIG. 2b shows a plan view of the embodiment of FIG. 2a.

FIG. 3 shows a cross section of an alternative embodiment of the invention.

FIGS. 4-6 show steps in a process to form the embodiment of FIG. 2.FIGS. 7 and 8 show steps in a second embodiment of the process to form the structure of FIG. 2.

FIGS. 9 through 11 show other embodiments of the invention.

### DESCRIPTION OF THE PREFERRED EMBODIMENT

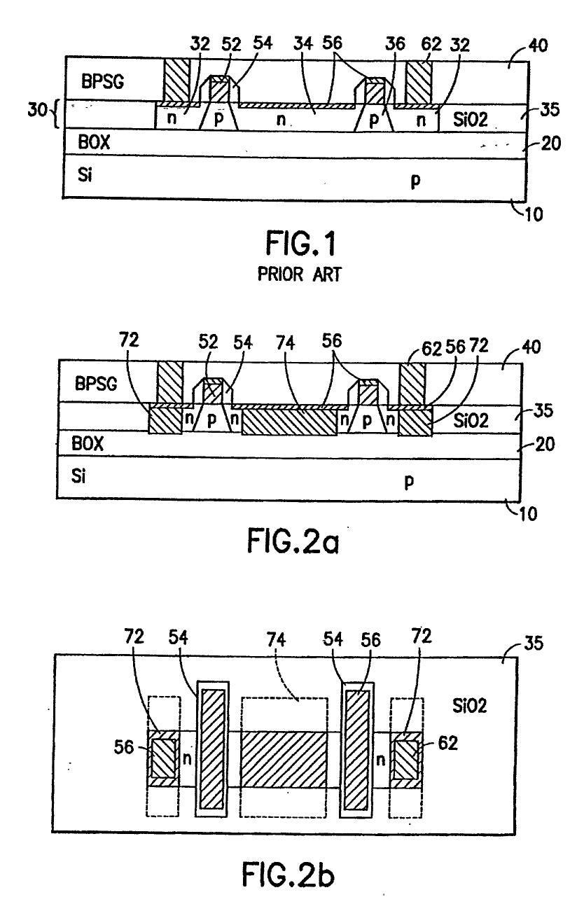

FIG. 1 shows in cross section a pair of NFETs according to the prior art, in which there is no gettering member. A p-type substrate 10 has a buried layer 20 (illustratively a SIMOX, Separation by IMplantation of OXygen, layer) and a device layer 30, containing two NFETs. The transistors have conventional construction with polycrystalline silicon (poly) gate 52, nitride (Si3N4) sidewalls 54, bodies 36 sources and drains 32 and 34, and suicides 56. The transistors are embedded in interlayer dielectric 40 having contacts 62 passing through it.

A corresponding cross section of a first embodiment of the invention is shown in FIG. 2a, which differs from FIG. 1 in having three gettering members 72 and 74 comprising poly regions that have been embedded in device layer 30. The gettering members 72 and 74 may pass through source-drain diffusion regions as shown or may pass through other portions of device layer 30 or adjacent STI 35. In this embodiment, the trench for holding gettering members 72 and 74 used oxide 20 as an etch stop, so that the members do not penetrate the oxide, but rather abut it. As is known in the art, gettering members 72 and 74 trap metallic contaminants, thus improving transistor performance and gate oxide reliability. FIG. 2b shows a top view of the layout of FIG. 2a, in which dotted line 74 indicates that gettering member 74 is non-critical in size and alignment. It may extend horizontally as permitted by the applicable design rules in order to increase the volume of poly available for gettering. The box denoted with numeral 35 represents the oxide-filled shallow trench isolation (STI) members that isolate transistors from one another. In this case, STI member 35 contains two transistors. This is a common layout that is used in 2-input NAND and NOR gates, among others. Layouts having only one transistor within the STI or having more than one may also be used.

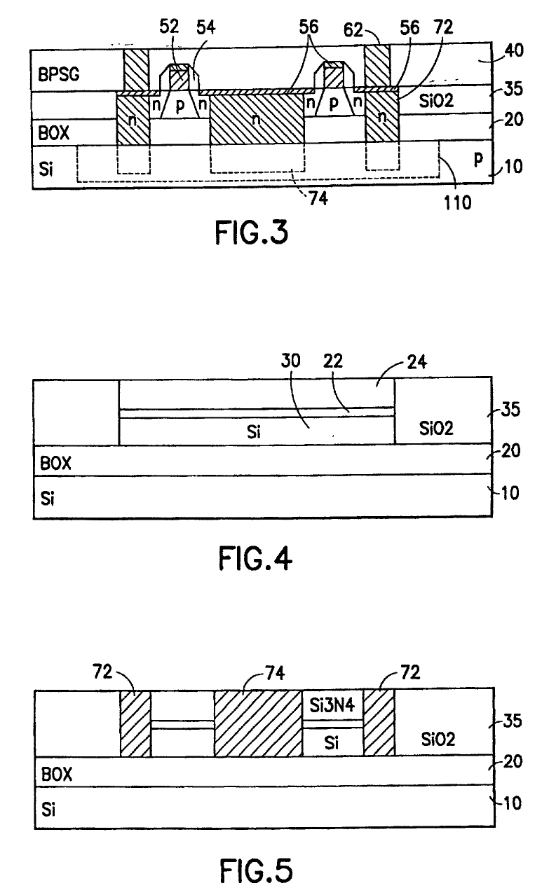

FIG. 3 illustrates the same view for an embodiment in which gettering members 72 and 74 penetrate oxide 20 and pass into substrate 10. This embodiment has the advantage of increasing the gettering volume by permitting access to substrate 10, since the diffusion length of metallic contaminants is very large. Another optional embodiment is one in which the gettering members stop at the top surface of substrate 10. Yet another embodiment is one in which the gettering members stop before the top surface of substrate 10, so that the doped gettering members to not make electrical contact with the substrate.

Choice of one of these options will depend on the requirements of the circuit being constructed. In the case in which the substrate is p-type and the gettering members are n-type and the substrate is conventionally biased at ground, the embodiment of FIG. 3 will have three reverse-biased diodes at the interfaces of the gettering members and substrate 10, assuming that the NFETS have either zero or positive voltages applied to their terminals. In that case, low frequency circuit operation will be unaffected by the connection between the substrate and the gettering members. This approach is also useful for decoupling applications. For the case where gettering members contact substrate 10, it may be desired to form them on a selective basis, to avoid excessive degradation of substrate characteristics. In substrate 10, a dotted line denoted with the numeral 110 represents schematically a conventional N-well that would be used if the transistors were PFETs. Those skilled in the art will readily be able to devise combinations of well bias and node bias that must be avoided or that offer advantages for different transistor polarities.

Referring now to FIG. 4, there is shown in cross section an early step in preparing the embodiment of FIG. 2. Preliminary steps, such as threshold implants, pad oxide 22 and pad nitride 24 have been performed. These preliminary steps will illustratively be referred to for the purposes of the claims as “preparing the substrate”. Additionally, STI 35 has been etched, filled with oxide (TEOS) and planarized, illustratively with chemical-mechanical polishing (CMP), using pad nitride 24 as a polish stop.

Next, in FIG. 5, the result of etching trenches for the gettering members, filling the trenches with poly and planarizing is shown. lllustratively,the etching chemistry for the getter trenches is fluorine based reactive ion etching (RIE) for the nitride and chlorine-based RIE for the silicon 30, stopping on oxide 20 as an etch stop. It is an advantageous feature of the invention that a slight penetration of oxide 20 by the trench does not matter and is actually favorable because it increases the gettering volume. Thus, an etch end point detect is not required and a timed etch is adequate. Preferably, the poly is doped with low concentrations 1019-1020 /cm3 of oxygen, nitrogen or carbon in order to suppress grain growth during high temperature anneals. Other materials, such as polycrystalline SiGE could also be used. Planarisation using a conventional poly CMP slurry and pad nitride 24 as a polish stop completes this step. Alternatively, the trenches for the getterers may be etched through a portion of the STI in addition to through the device layer. In this case, a timed oxide etch would be used in addition to the etching described above.

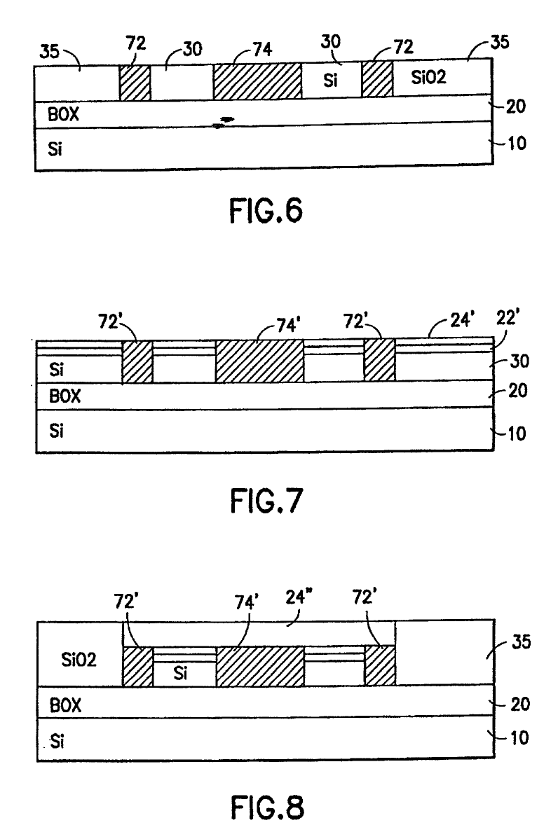

Next, pad nitride is stripped with a conventional phosphoric acid strip (or a dry etch); the poly gettering members are planarized using a dry etch or CMP. Pad oxide 22 (and the upper portion of STI 35) are removed with a etch, preferably, dilute or buffered HF. The result is shown in FIG. 6. The removal of the upper portion of STI 35 is effected primarily by the pad nitride/oxide strip.

An alternative sequence is etching trenches for the gettering members after the STI oxide deposition but before STI CMP. The sequence is: STI etch, STI deposition, gettering trench etch, gettering layer deposition, poly CMP and then STI CMP. A poly recess etch can optionally be used to adjust the height of the gettering layer with respect to the STI 35 and silicon 30.

The advantage of the alternate embodiment is that it saves a polishing step; the STI oxide and gettering material are polished together, stopping on the pad nitride. A disadvantage is reduced polish depth control because the slurry now has to accommodate two materials simultaneously and may not be optimized for either one.

Transistors are formed as shown in FIG. 2a, and interconnected to form the circuit by conventional back end processes.

Referring now to FIG. 7, there is shown a step in an alternative process in which the poly gettering sites are formed before the STI. Layers 10, 20, and 30 have been formed as in the first embodiment. Pad oxide 22′ and pad nitride 24′ (3-50 nm, 10 nm preferred) are put down conventionally and used as a hard mask to etch gettering trenches for the gettering members. The gettering trenches may stop on BOX 20, partially penetrate it, or pass through it to make contact with the substrate, as desired. Those skilled in the art are well aware of the appropriate etching chemistries. A layer of poly is put down and planarized by conventional CMP, using pad nitride 24′ as a polish stop, to leave the structure shown in FIG. 7, with gettering members 72′ and 74′. The poly layer may be doped with a low dose of oxygen, carbon or nitrogen to prevent grain growth, as before.

Next, a thicker (50-250 nm, 100 nm preferred) layer of pad nitride 24″ is formed and used as a mask to etch trenches for the STI. The excess oxide is polished off, using nitride 24″ as a polish stop, leaving the structure shown in FIG. 8. Nitrides 24″ and 24′ are stripped in a conventional wet or dry etch, (phosphoric acid preferred). Pad oxide 22′ is then removed. Preferably, the sequence is: a) remove pad oxide 22′ with a wet etch (dilute or buffered HF). This will remove the pad oxide and some of the excess STI member 35. Then, b) Perform a sacrificial gate oxidation on the exposed SOI 30 surface (illustratively a wet oxidation at about 800° C.—this will cause the low-doped poly to oxidize at 1.5× the SOI layer 30; highly doped (1019 /cm3 As) poly can oxidize at a rate as much as 4×. Channel doping into the SOI is done at this point. After a HF strip, the surface will be substantially coplanar. The result is substantially the same as shown in FIG. 6. Those skilled in the art will readily be able to devise alternative etching and/or CMP sequences to achieve the same result. This embodiment has the advantage that the gettering material is in place during more heat cycles than in other embodiments, thus improving the gettering effectiveness. It has the disadvantage that the size of the gettering regions is dependent on the alignment of the STI trenches, which was not the case for the first embodiment.

Next, a conventional sequence of gate oxide, gate conductor, diffusions, spacers, contacts, etc. is performed, leading to the structure shown in FIG. 3a.

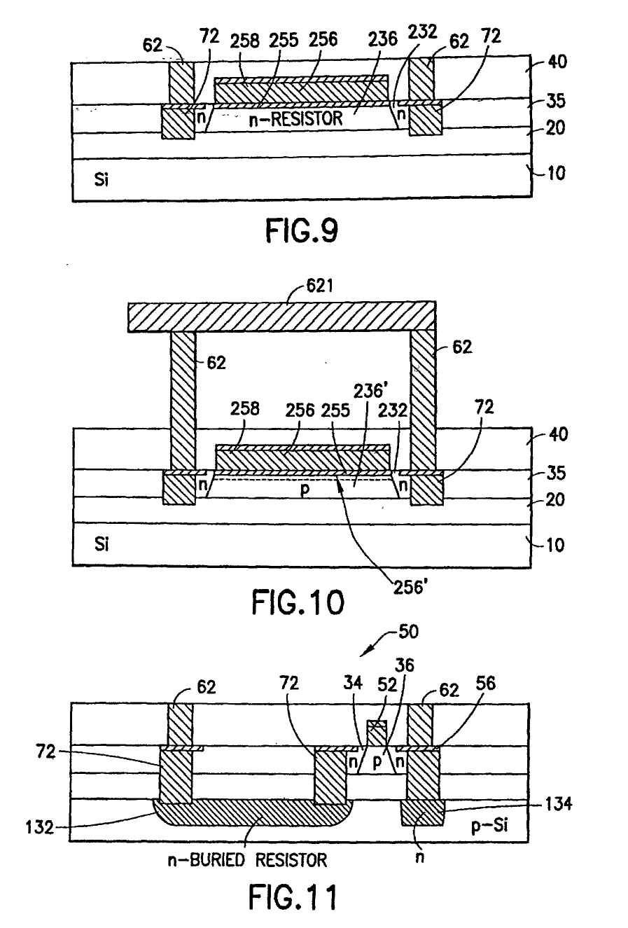

Referring now to FIG. 9, there is shown in cross section a gated resistor with integrated getterer. The same basic layers 10, 20, 30 and 40 are used as in the rest of the chip. In the device layer 30 there has been formed a structure that has two n-type elements 232 and a wide n-type area 236 that provides the resistance for the resistor. As an added feature, a gate 256, separated from the bulk resister 236 by oxide 255, controls the amount of free carriers in bulk 236 and thus the resistance of the device. Getterer members 72, at either end of the resistor provide traps for mobile metal ions and also provide part of a conductive path. Contacts 62 are provided to make contact with other parts of the circuit. If the process includes suicides, then the portions indicated by the thick dark lines may be permitted to be silicided. Those skilled in the art will appreciate that this structure is somewhat similar to that of a transistor, so that many process steps can be used for transistors and for this structure. Getterer members 62 provide traps for mobile ions and thus maintain the resistivity of the resistor at a more stable value than would be the case if the getterers were not there.

Referring now to FIG. 10, there is shown in cross section a capacitor with integrated getterer. The same basic layers 10, 20, 30 and 40 are used as in the rest of the chip. In the device layer 30 there has been formed a structure that has two n-type elements 232 and a wide p-type area 236′ that are similar in structure to the embodiment of FIG. 9, but provide different functions. Poly gate 256 (disposed over an oxide dielectric 255) is controlled by a voltage supply (not shown) to affect the formation of an inversion layer 256′. Charge can be stored in the capacitor using the inversion layer 256′ and gate 256 as the electrodes, with oxide 255 as the insulator. Getterers 72 both provide a conductive path and a supply of traps for mobile ions as before. Electrode 62′ shorts contacts 62 together to supply voltage to the lower capacitor plate 256′. Optionally, silicide 258 provides improved conductivity. Getterer members 62 provide traps for mobile ions and thus maintain the conductivity of inversion layer 256′ at a more stable value than would be the case if the getterers were not there.

Referring now to FIG. 11, there is shown an n-type buried resistor 132 that has been formed in p-type substrate 10 by ion implantation. On the left, getterer member 72 provides a conductive path from contact 62 to resistive element 132, while on the right, a second getterer 72 provides a conductive path to transistor 50, which optionally may be used to isolate the resistor in accordance with circuit needs. On the far right, a third getterer member provides contact to the other transistor terminal and also traps mobile ions on the other side of the transistor. Optional element 134 ties the substrate to the voltage of contact 62 (preferably ground) without taking extra space.

While the invention has been described in terms of several preferred embodiments, those skilled in the art will recognize that the invention can be practiced in various versions within the spirit and scope of the following claims.

We claim:

1. An SOI integrated circuit comprising an SOI wafer substrate including a buried insulator layer and a device layer disposed above said buried insulator layer;
a set of isolation members formed in said device layer, defining a set of active areas isolated from one another by said set of isolation members;
a set of devices formed in said set of active areas, at least some of which set of devices have gettering members formed within them.

2. An integrated circuit according to claim 1, in which:
said set of devices includes a set of transistors; and
said set of gettering members are formed within source/drain areas of said set of transistors.

3. An integrated circuit according to claim 2, in which:
said set of gettering members extends downward through said device layer, abutting said buried insulator layer.

4. An integrated circuit according to claim 2, in which:
said set of gettering members extends downward through said device layer, at least some of which set of gettering members penetrate said buried insulator layer.

5. An integrated circuit according to claim 2, in which:
said set of gettering members extends downward, at least some of which set of gettering members pass through said buried insulator layer and penetrate said substrate.

6. An integrated circuit according to claim 2, in which:
said set of devices includes a set of lateral gated diodes; and
said set of gettering members are formed within said set of active areas of said set of lateral gated diodes.

7. An integrated circuit according to claim 1, in which:
said set of devices includes a set of resistive elements formed within said device layer and connected to other elements of said integrated circuit through a conductive path that includes at least one getterer member.

8. An integrated circuit according to claim 7, further including a conductive gate disposed above said resistive element that controls the resistivity of said resistive element in accordance with a voltage applied to said conductive gate.

9. An integrated circuit according to claim 1, in which:
said set of devices includes a set of resistive elements formed within said substrate and connected to other elements of said integrated circuit through a conductive path that includes at least one getterer member.

10. An integrated circuit according to claim 1, in which:
said set of devices includes a set of capacitors formed within said device layer and connected to other elements of said integrated circuit through a conductive path that includes at least one getterer member.

11. An integrated circuit according to claim 10, in which said set of capacitors further include a conductive gate disposed above said device layer that controls an inversion layer formed in said device layer below said conductive gate, whereby said conductive gate and said inversion layer form electrodes of said capacitor.
